(19) United States
(12) Patent Application Publication
(10) Pub. No.: US 2010/0308326 A1
(43) Pub. Date: Dec. 9, 2010

(54) THIN-FILM TRANSISTOR ARRAY PANEL AND METHOD OF FABRICATING THE SAME

(75) Inventors: Young-Min KIM, Yongin-si (KR); Bo-Sung Kim, Seoul (KR); Yeon-Taek Jeong, Suwon-si (KR); Tae-Young Choi, Seoul (KR); Seon-Pil Jang, Seoul (KR); Seung-Hwan Cho, Suwon-si (KR); Bo-Kyoung Ahn, Incheon (KR); Byeong-Soo Bae, Daejeon (KR); Seok-Jun Seo, Daejeon (KR)

Correspondence Address: H.C. PARK & ASSOCIATES, PLC, 8500 LEESBURG PIKE, SUITE 7500, VIENNA, VA, 22182, US

(73) Assignees: Samsung Electronics Co., Ltd., Suwon-si (KR); Korea Advanced Institute of Science and Technology, Daejeon (KR)

(21) Appl. No.: 12/790,188

(22) Filed: May 28, 2010

(30) Foreign Application Priority Data
Jun. 4, 2009 (KR) 10-2009-0049564

(51) Int. Cl. H01L 29/786; H01L 21/34

(52) U.S. Cl. 257/43; 438/104; 257/59; 257/E29.296; 257/E21.459; 438/34

(57) ABSTRACT

A thin-film transistor array panel includes: an insulating substrate; an oxide semiconductor layer that is formed on the insulating substrate and includes a metal inorganic salt and zinc acetate; a gate electrode overlapping with the oxide semiconductor layer; a gate insulating film that is interposed between the oxide semiconductor layer and the gate electrode; and a source electrode and a drain electrode that at least partially overlap the oxide semiconductor layer and are separated from each other.

### CROSS REFERENCE TO RELATED APPLICATION

This application claims priority from and the benefit of Korean Patent Application No. 10-2009-0049564, filed on Jun. 4, 2009, which is hereby incorporated by reference for all purposes as if fully set forth herein.

### BACKGROUND OF THE INVENTION

1. Field of the Invention

Exemplary embodiments of the present invention relate to a thin-film transistor array panel and a method of fabricating the same, and more particularly, to a thin-film transistor array panel including an oxide semiconductor layer, which has superior stability and electrical characteristics and which can be easily manufactured, and a method of fabricating the thin-film transistor array panel.

2. Discussion of the Background

Liquid crystal displays (LCDs) are one of the most widely used types of flat panel displays. Generally, an LCD includes a pair of display panels having electrodes and a liquid crystal layer interposed between the display panels. In the LCD, voltages are applied to the electrodes to generate an electric field. The electric field determines the alignment of liquid crystal molecules of the liquid crystal layer, thereby controlling polarization of incident light. As a result, a desired image is displayed on the LCD.

Generally, the LCD includes a thin-film transistor for switching each pixel. A thin-film transistor is a switching device including, as its three terminals, a gate electrode, which receives a switching signal, a source electrode, which receives a data voltage, and a drain electrode, which outputs the data voltage. The thin-film transistor further includes an active layer between the gate electrode and the source and drain electrodes. The active layer is usually made of amorphous silicon or polycrystalline silicon.

Polycrystalline silicon thin-film transistors have a higher electron mobility than amorphous silicon thin-film transistors. Thus, polycrystalline silicon thin-film transistors offer a higher driving speed and a greater output current than amorphous thin-film transistors. However, polycrystalline silicon thin-film transistors are inferior to amorphous silicon thin-film transistors in terms of cost and uniformity.

Therefore, it may be desired to develop a thin-film transistor that has advantages of both an amorphous silicon thin-film transistor and a polycrystalline silicon thin-film transistor.

### SUMMARY OF THE INVENTION

Exemplary embodiments of the present invention provide a thin-film transistor array panel including an oxide semiconductor layer that may have superior stability and electrical characteristics and that can be easily manufactured.

Exemplary embodiments of the present invention also provide a method of fabricating a thin-film transistor array panel including an oxide semiconductor layer which has superior stability and electrical characteristics and which can be easily manufactured.

Additional features of the invention will be set forth in the description which follows, and in part will be apparent from the description, or may be learned by practice of the invention.

An exemplary embodiment of the present invention discloses a thin-film transistor array panel including: an insulating substrate. An oxide semiconductor layer is formed on the insulating substrate and includes a metal inorganic salt and zinc acetate. A gate electrode is overlapping with the oxide semiconductor layer. A gate insulating film is interposed between the oxide semiconductor layer and the gate electrode. A source electrode and a drain electrode at least partially overlap the oxide semiconductor layer and are separated from each other.

An exemplary embodiment of the present invention also discloses a method of fabricating a thin-film transistor array panel. The method includes: forming an oxide semiconductor layer, which includes a metal inorganic salt and zinc acetate, on an insulating substrate; forming a gate electrode to be overlapped with the oxide semiconductor layer; forming a gate insulating film between the oxide semiconductor layer and the gate electrode; and forming a source electrode and a drain electrode to at least partially overlap the oxide semiconductor layer and to be separated from each other.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1A is a layout diagram of a thin-film transistor array panel according to a first exemplary embodiment of the present invention.

FIG. 1B is a cross-sectional view of the thin-film transistor array panel taken along line A-A′ of FIG. 1A.

FIG. 2 is a graph illustrating the output of a thin-film transistor including an oxide semiconductor layer.

FIG. 3 is a graph illustrating a transfer curve of the thin-film transistor including the oxide semiconductor layer.

FIG. 4, FIG. 5, FIG. 6, FIG. 7, FIG. 8, and FIG. 9 are cross-sectional views sequentially illustrating processes included in an exemplary embodiment of a method of fabricating the thin-film transistor array panel according to the first exemplary embodiment of the present invention.

FIG. 10 is a cross-sectional view of a thin-film transistor array panel according to a second exemplary embodiment of the present invention.

### DETAILED DESCRIPTION OF THE ILLUSTRATED EMBODIMENTS

Advantages and features of the present invention and methods of accomplishing the same may be understood more readily by reference to the following detailed description of exemplary embodiments and the accompanying drawings. The present invention may, however, be embodied in many different forms and should not be construed as being limited to the embodiments set forth herein. Rather, these embodiments are provided so that this disclosure is thorough, and will fully convey the scope of the invention to those skilled in the art. In the drawings, the size and relative sizes of layers and regions may be exaggerated for clarity Like reference numerals in the drawings denote like elements.

It will be understood that when an element or layer is referred to as being “on” or “connected to” another element or layer, the element or layer can be directly on or directly connected to the other element or layer, or intervening elements or layers may be present. In contrast, when an element is referred to as being “directly on” or “directly connected to” another s element or layer, there are no intervening elements or layers present. As used herein, the term “and/or” includes any and all combinations of one or more of the associated listed items.

Spatially relative terms, such as “below”, “beneath”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

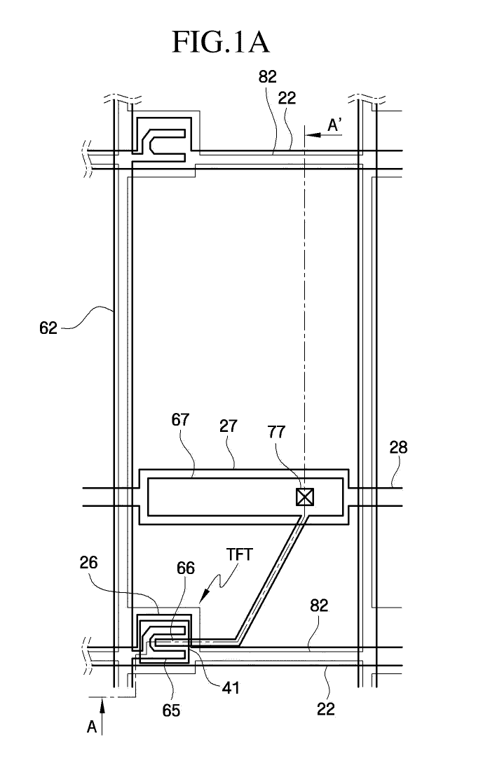

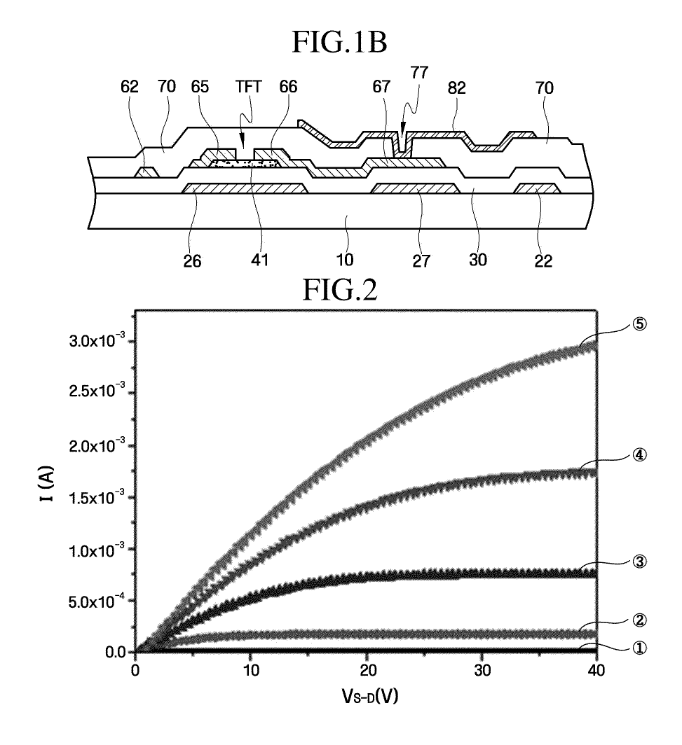

Hereinafter, a thin-film transistor array panel according to a first exemplary embodiment of the present invention will be described in detail with reference to FIG. 1A and FIG. 1B. FIG. 1A is a layout diagram of the thin-film transistor array panel according to the first exemplary embodiment of the present invention. FIG. 1B is a cross-sectional view of the thin-film transistor array panel taken along line A-A′ of FIG. 1A.

Referring to FIG. 1A and FIG. 1B, gate wiring, which transmits a gate signal, is formed on an insulating substrate 10. The gate wiring includes a gate line 22 and a gate electrode 26. The gate line 22 extends horizontally, and the gate electrode 26 of a thin-film transistor is connected to the gate line 22 and protrudes from the gate line 22.

Storage wiring, which applies a storage voltage, is also formed on the insulating substrate 10. The storage wiring includes a storage line 28 and a storage electrode 27. The storage line 28 extends horizontally across a pixel region to be substantially parallel to the gate line 22. The storage electrode 27 is wider than the storage line 28 and is connected to the storage line 28.

The storage electrode 27 is overlapped by a drain electrode extension portion 67 connected to a pixel electrode 82, which will be described later, to form a storage capacitor that improves the charge storage capability of a pixel. The shapes and dispositions of the storage electrode 27 and the storage line 28 may vary. If sufficient storage capacitance can be generated by overlapping the pixel electrodes 82 and the gate line 22, the storage line 27 and the storage electrode 28 may be omitted.

The gate wiring (i.e., the gate line 22 and the gate electrode 26) and the storage wiring (i.e., the storage electrode 27 and the storage line 28) may be made of aluminum (Al)-based metal, such as aluminum and an aluminum alloy, silver (Ag)-based metal, such as silver and a silver alloy, copper (Cu)-based metal such as copper and a copper alloy, molybdenum (Mo)-based metal, such as molybdenum and a molybdenum alloy, chrome (Cr), titanium (Ti) or tantalum (Ta).

In addition, the gate wiring and the storage wiring may have a multi-film structure composed of two conductive films (not shown) with different physical characteristics. One of the two conductive films may be made of metal with low resistivity, such as aluminum-based metal, silver-based metal or copper-based metal, in order to reduce a signal delay or a voltage drop of the gate wiring and the storage wiring. The other one of the conductive films may be made of a different material, in particular, a material having superior contact characteristics with indium tin oxide (ITO) and indium zinc oxide (IZO), such as molybdenum-based metal, chrome, titanium, or tantalum. Examples of multi-film structures include a chrome lower film and an aluminum upper film and an aluminum lower film and a molybdenum upper film. However, the present invention is not limited thereto. The gate wiring and the storage wiring may be formed of various metals and conductors.

A gate insulating film 30 is formed on the insulating substrate 10 and the gate wiring. The gate insulating film 30 may be made of silicon oxide (SiOx), silicon nitride (SiNx), or silicon oxynitride (SiON).

An oxide semiconductor layer 41, which contains a metal inorganic salt and zinc acetate (Zn(O₂CCH₃)₂), is formed on the gate insulating film 30. The metal inorganic salt may contain at least one metal selected from lithium (Li), sodium (Na), potassium (K), rubidium (Rb), cesium (Cs), beryllium (Be), magnesium (Mg), calcium (Ca), strontium (Sr), barium (Ba), titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), aluminum (Al), gallium (Ga), indium (In), thallium (Tl), silicon (Si), germanium (Ge), tin (Sn), lead (Pb), phosphorus (P), arsenic (As), antimony (Sb) and bismuth (Bi), and at least one inorganic salt selected from fluorine (F), chlorine (Cl), bromine (Br), iodine (I), NO₃, SO₄, PO₄, C₂O₄, ClO₄ and BF₄.

Specifically, a metal compound solution may be fabricated using a metal inorganic salt and zinc acetate and then coated on the gate insulating film 30. Here, the metal compound solution may be coated on the gate insulating film 30 using one of spin coating, dip coating, bar coating, screen printing, slide coating, roll coating, spray coating, slot coating, dip-pen, inkjet, and nano-dispensing methods.

Next, the metal compound solution coated on the gate insulating film 30 may be oxidized in a heat treatment process to complete the oxide semiconductor layer 41. A specific method of forming the oxide semiconductor layer 41 will be described later.

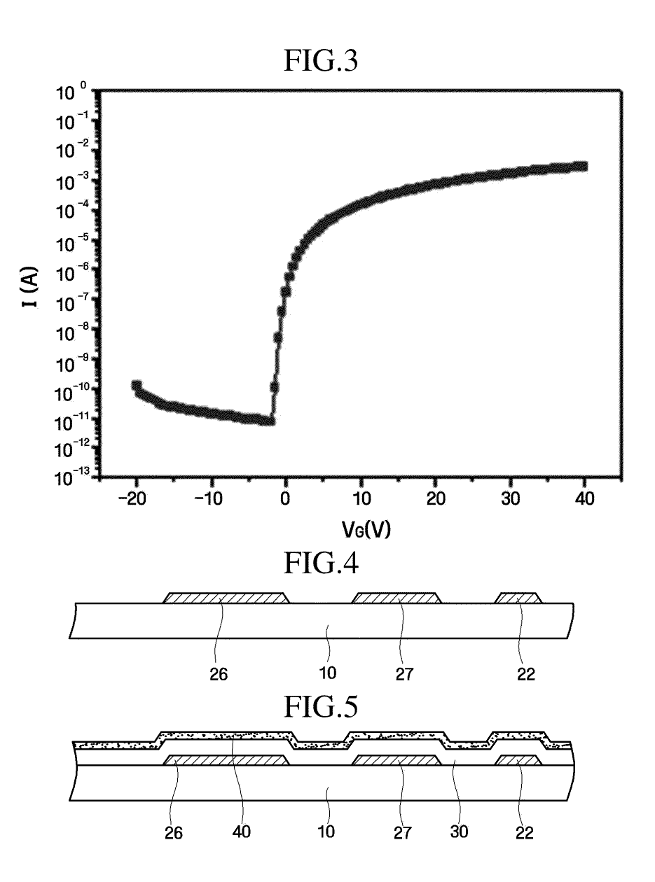

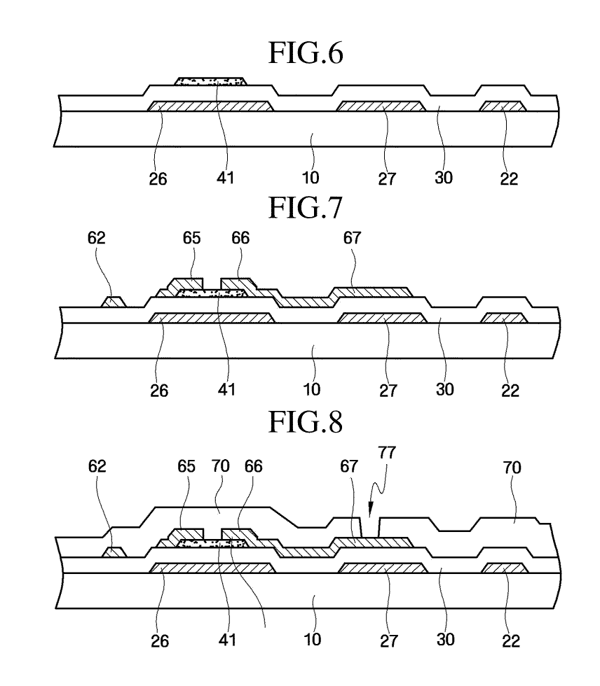

Characteristics of the oxide semiconductor layer 41 will now be described with reference to FIG. 2 and FIG. 3. FIG. 2 is a graph illustrating the output of a thin-film transistor including the oxide semiconductor layer 41. FIG. 3 is a graph illustrating a transfer curve of the thin-film transistor including the oxide semiconductor layer 41.

Referring to FIG. 2, the horizontal axis is a voltage V_{S-D} between a source electrode 65 and a drain electrode 66, and the vertical axis is a current “I” flowing through the oxide semiconductor layer 41.

Curve “1” represents the result of applying 0 V to the gate electrode 26, and curve “2” represents the result of applying 10 V to the gate electrode 26. In addition, curve “3” represents the result of applying 20 V to the gate electrode 26, curve “4” represents the result of applying 30 V to the gate electrode 26, and curve “5” represents the result of applying 40 V to the gate electrode 26.

It can be understood from curves “1”, “2”, “3”, “4” and “5” that the current “I” flowing through the oxide semiconductor layer 41 is not proportional to the voltage V_{S-D} between the source electrode 65 and the drain electrode 66. That is, the current “I” flowing through the oxide semiconductor layer 41 does not increase linearly as the voltage V_{S-D} between the source electrode 65 and the drain electrode 66 increases. This phenomenon in which an increase in the current “I” flowing through the oxide semiconductor layer 41 is saturated as the voltage V_{S-D} between the source electrode 65 and the drain electrode 66 increases is one of semiconductor characteristics. Therefore, the oxide semiconductor layer 41 containing a metal inorganic salt and zinc acetate is very suitable for forming a channel region of a thin-film transistor.

The graph of FIG. 3 illustrates the variation in the current “I” flowing through the oxide semiconductor layer 41 with respect to a gate voltage V_{G}. Referring to FIG. 3, the thin-film transistor including the oxide semiconductor layer 41 which contains a metal inorganic salt and zinc acetate has a very high ON/OFF current ratio of more than 10⁸ and a threshold voltage of 1.71 V. That is, the thin-film transistor exhibits characteristics of an enhancement-mode transistor. Therefore, the oxide semiconductor layer 41 containing a metal inorganic salt and zinc acetate can maintain the appropriate performance required to form a channel region of the thin-film transistor. In addition, the oxide semiconductor layer 41 has a high saturation mobility of 14.11 cm²/Vs.

Referring back to FIG. 1A and FIG. 1B, the oxide semiconductor layer 41 may contact a passivation layer 70 formed thereon and the gate insulating film 30 formed thereunder. Here, the gate insulating film 30 and the passivation layer 70 may be made of SiOx, SiNx, or SiON. As an element (such as silicon) contained in the gate insulating film 30 and the passivation layer 70 is combined with oxygen, an oxygen vacancy may be formed in the oxide semiconductor layer 41.

The above-mentioned materials that constitute the oxide semiconductor layer 41 exhibit good ohmic contact characteristics with data wiring (i.e., a data line 62, the source electrode 65, the drain electrode 66, and a drain electrode extension portion 67) which will be described later. Thus, there is no need to form an ohmic contact layer, thereby reducing manufacturing time. In addition, the oxide semiconductor layer 41, despite being amorphous, has a high effective charge mobility, and a conventional process of fabricating amorphous silicon can be used to form the oxide semiconductor layer 41. Therefore, the oxide semiconductor layer 41 can be applied in large-screen display devices.

In an oxide thin-film transistor according to the current exemplary embodiment, the oxide semiconductor layer 41 and the data wiring are patterned in different shapes. However, if a 4-mask process is applied, the oxide semiconductor layer 41 can be patterned in s substantially the same shape as the data wiring, except for a channel region of the oxide thin-film transistor. This is because the oxide semiconductor layer 41 and the data wiring are patterned using one etch mask. In the current exemplary embodiment, the structure of the oxide thin-film transistor manufactured by a 5-mask process is suggested as an example. However, the present invention is not limited to the 5-mask process. That is, it will be apparent to those skilled in the art that mask processes (such as a 3-mask process and a 4-mask process) other than the 5-mask process can also be used without departing from the core spirit of the present invention.

The data wiring is formed on the oxide semiconductor layer 41 and the gate insulating film 30. The data wiring includes the data line 62, the source electrode 65, the drain electrode 66, and the drain electrode extension portion 67. The data line 62 extends vertically to is cross the gate line 22 and thus define a pixel. The source electrode 65 branches off from the data line 62 and extends onto the oxide semiconductor layer 41. The drain electrode 66 is separated from the source electrode 65 and formed on the oxide semiconductor layer 41 to face the source electrode 65 with respect to the gate electrode 26 or the channel region of the oxide thin-film transistor. The drain electrode extension portion 67 has a large area, extends from the drain electrode 66, and overlaps the storage electrode 27.

The oxide semiconductor layer 41 overlaps the gate electrode 26. At least part of each of the source electrode 65 and the drain electrode 66 overlaps the oxide semiconductor layer 41. The source electrode 65 and the drain electrode 66 are separated from each other. As long as the above relationship between the gate electrode 26, the oxide semiconductor layer 41, the source electrode 65, and the drain electrode 66 is maintained, the order in which they are disposed or positions at which they are located in the oxide thin-film transistor may vary.

The data wiring (i.e., the data line 62, the source electrode 65, the drain electrode 66, and the drain electrode extension portion 67) may be made of a material that can form an ohmic contact with the oxide semiconductor layer 41 when directly contacting the oxide semiconductor layer 41. For example, if the data wiring is made of a material having a lower work function than that of the material of the oxide semiconductor layer 41, an ohmic contact can be formed between the two layers.

To form an ohmic contact with the oxide semiconductor layer 41, the data wiring may have a mono-film structure or a multi-film structure composed of a material or materials selected from Ni, Co, Ti, Ag, Cu, Mo, Al, Be, Nb, Au, Fe, Se, and Ta. In addition, an alloy of Ni, Co, Ti, Ag, Cu, Mo, Al, Be, Nb, Au, Fe, Se, and Ta and one or more additional elements selected from Ti, Zr, W, Ta, Nb, Pt, Hf, O, and N may be used.

When the oxide semiconductor layer 41 directly contacts metal such as Al, Cu, and Ag, it may react with the metal, or diffusion may occur. Thus, if the data wiring is made of such a metal, characteristics of the oxide thin-film transistor including the data wiring may deteriorate. Also, ohmic contact characteristics of the data wiring with ITO or IZO, which is generally used to form the pixel electrode 82, may deteriorate. Therefore, the data wiring may be formed as a double film or a triple film.

When Al or an alloy of Al and at least one of Nd, Sc, C, Ni, B, Zr, Lu, Cu, and Ag is used to form the data wiring, the data wiring may be formed as a multi-film composed of an Al or Al alloy film and a heterogeneous film disposed on and/or under the Al or Al alloy film.

Examples of the multi-film include a double film composed of Mo or a Mo alloy/Al or an Al alloy, Ti or a Ti alloy/Al or an Al alloy, Ta or a Ta alloy/Al or an Al alloy, Ni or a Ni alloy/Al or an Al alloy, or Co or a Co alloy/Al or an Al alloy, and a triple film composed of Ti or a Ti alloy/Al or an Al alloy/Ti or a Ti alloy, Ta or a Ta alloy/Al or an Al alloy/Ta or a Ta alloy, Ti or a Ti alloy/Al or an Al alloy/TiN, Ta or a Ta alloy/Al or an Al alloy/TaN, Ni or a Ni alloy/Al or an Al alloy/Ni or a Ni alloy, Co or a Co alloy/Al or an Al alloy/Co or a Co alloy, or Mo or a Mo alloy/Al or an Al alloy/Mo or a Mo alloy. Here, each alloy may contain at least one of Mo, W, Nb, Zr, V, O, and N.

When Cu or a Cu alloy is used to form the data wiring, there is no significant problem with ohmic contact characteristics between the data wiring and the pixel electrode 82. Therefore, the data wiring may be formed as a double film composed of a Cu or Cu alloy film and a Mo, Ti, or Ta film interposed between the oxide semiconductor layer 41 and the Cu or Cu alloy film. Examples of the double film include Mo or a Mo alloy/Cu, Ti or a Ti alloy/Cu, TiN or a TiN alloy/Cu, Ta or a Ta alloy/Cu, and TiOx/Cu.

At least part of the source electrode 65 overlaps the oxide semiconductor layer 41. In addition, the drain electrode 66 faces the source electrode 65 with respect to the channel region of the oxide thin-film transistor, and at least part of the drain electrode 66 overlaps the oxide semiconductor layer 41.

The drain electrode extension portion 67 overlaps the storage electrode 27. The drain electrode extension portion 67 and the storage electrode 27 form a storage capacitor with the gate insulating film 30 interposed therebetween. When the storage electrode 27 is not formed, the drain electrode extension portion 67 may not be formed.

The passivation layer 70 is formed on the data wiring (i.e., the data line 62, the source electrode 65, the drain electrode 66, and the drain electrode extension portion 67) and a portion of the oxide semiconductor layer 41 exposed by the data wiring. The passivation layer 70 contacts the oxide semiconductor layer 41. Thus, like the gate insulating film 30, the passivation layer 70 may be made of SiOx, SiNx, or SiON. In order to enhance the quality of the passivation layer 70, an element, which belongs to group III or V of the periodic table, may be doped to form the passivation layer 70.

A contact hole 77 exposing the drain electrode extension portion 67 is formed in the passivation layer 70. The pixel electrode 82, which is electrically connected to the drain electrode 66 by the contact hole 77, is formed on the passivation layer 70. The pixel electrode 82 may be made of a transparent conductor, such as ITO or IZO, or a reflective conductor such as aluminum.

When a data voltage is applied to the pixel electrode 82, the pixel electrode 82 generates an electric field together with a common electrode (not shown) which is disposed on an upper panel (not shown) facing the thin-film transistor array panel. The electric field determines the alignment of liquid crystal molecules (not shown) of a liquid crystal layer (not shown) interposed between the pixel electrode 82 and the common electrode (not shown).

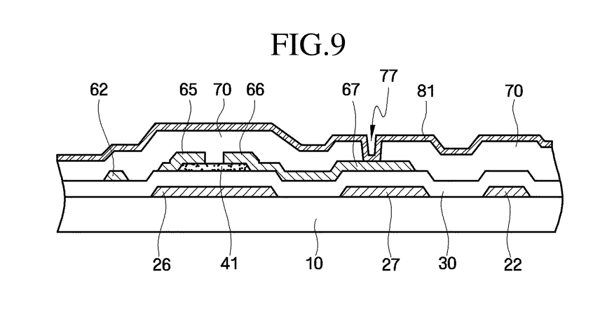

Hereinafter, an exemplary embodiment of a method of fabricating the thin-film transistor array panel according to the first exemplary embodiment of the present invention will be described in detail with reference to FIG. 1A and FIG. 1B and FIG. 4, FIG. 5, FIG. 6, FIG. 7, FIG. 8, and FIG. 9. FIG. 4 through FIG. 9 are cross-sectional views sequentially illustrating processes included in the exemplary embodiment of the method of fabricating the thin-film transistor array panel according to the first exemplary embodiment of the present invention.

Referring to FIG. 1A and FIG. 4, the gate line 22, the gate electrode 26, the storage electrode 27, and the storage line 28 are formed on the insulating substrate 10.

The insulating substrate 10 may be made of glass, such as soda lime glass or borosilicate glass, or plastic. To form the gate wiring (i.e., the gate line 22 and the gate electrode 26), a gate wiring conductive film is formed on the insulating substrate 10 by, e.g., sputtering. When soda lime glass, which is vulnerable to damage from uneven and/or high temperature, is used to form the insulating substrate 10, low-temperature sputtering may be employed.

Next, the gate wiring conductive film is patterned by wet etching or dry etching. For wet etching, phosphoric acid, nitric acid, or acetic acid may be used as an etchant. For dry etching, a chorine (Cl)-based etch gas, such as Cl₂ or BCl₃, may be used.

Referring to FIG. 1A and FIG. 5, the gate insulating film 30 is formed on the insulating substrate 10 and the gate wiring (i.e., the gate line 22 and the gate electrode 26) using plasma enhanced chemical vapor deposition (PECVD) or reactive sputtering.

Then, a metal compound solution containing a metal inorganic salt and zinc acetate is coated on the gate insulating film 30 to form a metal compound coating film. As described above, the metal inorganic salt may contain metal selected from lithium (Li), sodium (Na), potassium (K), rubidium (Rb), cesium (Cs), beryllium (Be), magnesium (Mg), calcium (Ca), strontium (Sr), barium (Ba), titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), aluminum (Al), gallium (Ga), indium (In), thallium (Tl), silicon (Si), germanium (Ge), tin (Sn), lead (Pb), phosphorus (P), arsenic (As), antimony (Sb) and bismuth (Bi), and inorganic salt selected from fluorine (F), chlorine (Cl), bromine (Br), iodine (I), NO₃, SO₄, PO₄, C₂O₄, ClO₄ and BF₄.

A stabilizer may also be contained in the metal compound solution. The stabilizer may contain at least one of diketone, amino alcohol, and polyamine.

Specifically, diketone may contain acetylacetone. In addition, amino alcohol may contain ethanolamine, diethanolamine, or triethanolamine. For example, amino alcohol may contain any one of AgNO₃, CH₅NO.HCl, C₂H₇NO, C₂H₇NO.HCl, C₂H₈N₂O, C₃H₉NO, C₃H₉NO₂, C₃H₉NO₂.HCl, C₃H₁₀N₂O, C₄H₆F₃NO₂, C₄H₉NO₂, C₄H₁₁NO, C₄H₁₁NO₂, C₄H₁₁NO₂.HCl, C₄H₁₁NO₃, C₄H₁₁NS.HCl, C₄H₁₂N₂O.2HCl, C₄H₁₂N₂O, C₄H₁₂N₂O₂.2HCl, C₅H₈F₃NO₂, C₅H₁₁NO.HCl, C₅H₁₁NO₂, C₅H₁₃NO, C₅H₁₃NO₂, C₅H₁₄N₂O, C₆H₁₀F₃NO₂, C₆H₁₁NO₃, C₆H₁₃NO, C₆H₁₃NO.HCl, C₆H₁₅NO, C₆H₁₅NO₂, C₆H₁₅NO₃, C₃, C₆H₁₆N₂O₂, C₇H₈ClNO, C₇H₉NO, C₇H₉NO₂.HBr, C₇H₁₀N₂O.2HCl, C₇H₁₂F₃NO₂, C₇H₁₃NO₃, C₇H₁₅NO.HCl, C₇H₁₅NO₃, C₇H₁₇NO, C₇H₁₇NO₂, C₇H₁₈N₂O, C₈H₉ClN₂O₃, C₈H₁₁NO, C₈H₁₁NO₂. HCl, C₈H₁₁NO₂, C₈H₁₁NO₂.HBr, C₈H₁₁NO₂.HCl, C₈H₁₁NO₃.HCl, C₈H₁₁NO₃.HBr, C₈H₁₁N₃O₃, C₈C₁₄F₃NO₂, C₈H₁₁NO, C₈H₁₅NO₃, C₈H₁₇NO₄, C₈H₁₉NO, C₈H₁₉NO₂, C₉H₁₂ClNO, C₉H₁₃NO, C₉H₁₃NO.HCl, C₉H₁₃NO₂.HCl, C₉H₁₃NO₃.HCl, C₉H₁₇NO₃, C₉H₁₉NO₃, C₁₀H₁₃NO₃, C₁₀H₁₅NO, C₁₀H₁₅NO.HCl, C₁₀H₁₅NO, C₁₀ₒH₁₅NO₂, C₁₀H₁₆N₂O.H₂SO₄.H₂O, C₁₀H₁₇NO, C₁₀H₁₉NO₃, C₁₀H₂₁NO₃, C₁₀H₂₃NO, C₁₁H₁₅NO₃, C₁₁H₁₅NO₄, C₁₁H₁₇NO, C₁₁H₁₇NO.HCl, C₁₁H₁₇NO₂, C₁₁H₁₇NO₃.HCl, C₁₁H₂₀N₂O₅S, C₁₁H₂₁NO₃, C₁₂H₁₇NO₃, C₁₂H₁₉N₃O₅, C₁₃H₃₁NO₅Si, C₁₄H₁₉NO₃, C₁₄H₁₉N₃O.C₆H₈O₇, C₁₄H₂₁NO₃, C₁₅H₁₂F₆N₂O₂, C₁₅H₃₃NO₆, C₁₆H₂₅NO.HBr, C₁₇H₁₇NO₃, C₁₇H₂₁NO, C₁₇H₂₂N₂O, C₁₈H₁₉NO₃, C₁₉H₂₁NO₄, C₂₀H₂₃NO₃, C₂₅H₂₉NO₈S₃, C₂₇H₃₀N₆O, and C₂₇H₃₂Cl₂N₂O₄.

Polyamine may contain ethylenediamine or 1,4-diaminobutane. For example, polyamine may contain any one of C₂H₈N₂, C₃H₁₀N₂, C₄H₁₂N₂, C₅H₁₄N₂, C₅H₁₅N₃.3HCl, C₅H₁₅N₃, C₅H₁₆N₂Si, C₆H₆Cl₂N₂, C₆H₇BrN₂, C₆H₇ClN₂, C₆H₇N₃O₂, C₆H₈N₂, C₆H₁₂N₄, C₆H₁₄N₂, C₆H₁₆N₂, C₆H₁₇N₃, C₆H₁₈ClN₃Si, C₆H₁₈N₄, C₆H₁₈N₄.xH₂O, C₇H₆BrF₃N₂, C₇H₇F₃N₂, C₇H₉FN₂, C₇H₁₀N₂, C₇H₁₈N₂, C₇H₁₉N₃, C₇H₂₀N₄, C₈H₁₀N₂O₂, C₈H₁₂N₂, C₈H₂₀N₂, C₈H₂₀N₂O, C₈H₂₁N₃, C₈H₂₂N₄, C₈H₂₃N₅, C₉H₁₄N₂, C₉H₁₄N₂O₂S, C₉H₂₀N₂, C₉H₂₂N₂, C₉H₂₂N₂O, C₉H₂₃N₃, C₉H₂₄N₄, C₁₀H₁₀N₂, C₁₀H₁₆N₂, C₁₀H₂₂N₂, C₁₀H₂₄N₂, C₁₀H₂₄N₂O₃, C₁₀H₂₅N₃, C₁₀H₂₈N₆, C₁₁H₁₈N₂, C₁₁H₁₈N₂O, C₁₁H₂₂N₂O₂, C₁₁H₂₆N₂, C₁₂H₁₁ClN₂, C₁₂H₁₂N₂, C₁₂H₁₂N₂O, C₁₂H₁₄N₄, C₁₂H₂₈N₂, C₁₂H₂₉N₃, C₁₂H₃₀N₄, C₁₃H₁₂N₂, C₁₃H₁₄N₂, C₁₃H₂₆N₂, C₁₄H₁₈, N₂, C₁₄H₂₂N₂, C₁₄H₃₂N₂, C₁₅H₃₀N₂, C₁₅H₃₅N₃, C₁₅H₃₆N₄, C₁₆H₂₀N₂, C₁₇H₂₂N₂, C₁₈H₃₁N, C₂₀H₁₆N₂, C₂₂H₄₈N₂, C₂₂H₄₉N₃, C₂₅H₂₀N₂, C₂₆H₃₈N₄, C₂₆H₄₀N₂, C₂₉H₃₀N₂, and C₂₉H₄₆N₂.

A material containing alcohol may be used as a solvent of the metal compound solution.

The metal compound solution may be fabricated by appropriately combining the above materials. For example, the metal compound solution may be fabricated by adding 20 ml of 2-methoxyethanol (i.e., a solvent) and 0.012 mol of acetylacetone (i.e., a stabilizer) to 0.003 mol of zinc acetate and 0.003 mol of tin (II) chloride and mixing them for approximately six hours.

The metal compound solution may be coated on the gate insulating film 30 using one of spin coating, dip coating, bar coating, screen printing, slide coating, roll coating, spray coating, slot coating, dip-pen, inkjet, and nano-dispensing methods.

Next, the metal compound solution coated on the gate insulating film 30, that is, the metal compound coating film, is heat-treated to form a metal oxide film 40. In the heat-treatment process, the metal compound coating film may be heated to about 100 to about 500° C. As a result, the metal inorganic salt, the zinc acetate, and the solvent may be hydrolyzed to form a metal oxide film 40.

Referring to FIG. 1A and FIG. 6, the metal oxide film 40 shown in FIG. 5 is patterned to form the oxide semiconductor layer 41. In the current exemplary embodiment, the oxide semiconductor layer 41 may be etched before the data wiring (i.e., the data line 62, the source electrode 65, the drain electrode 66, and the drain electrode extension portion 67). However, the oxide semiconductor layer 41 and the data wiring may also be simultaneously etched in order to reduce the number of masks used.

Referring to FIG. 1A and FIG. 7, the data wiring is formed on the gate insulating film 30 and the oxide semiconductor layer 41 by, e.g., sputtering.

A data wiring conductive layer is formed on the gate insulating film 30 and the oxide semiconductor layer 41. The data wiring conductive layer may be etched to form the data wiring (i.e., the data line 62, the source electrode 65, the drain electrode 66, and the drain electrode extension portion 67).

The source electrode 65 and the drain electrode 66 are separated from each other with respect to the gate electrode 26, and the drain electrode extension portion 67 extending from the drain electrode 66 overlaps the storage electrode 27. The source electrode 65 and the drain electrode 66 may be deposited using various methods such as electron-beam deposition.

Referring to FIG. 8, the passivation layer 70 is formed by PECVD or reactive sputtering. Then, the passivation layer 70 is patterned by a photolithography process to form the contact hole 77, which exposes the drain electrode extension portion 67.

Referring to FIG. 9, a pixel electrode conductive film 81 connected to part of the data wiring is formed on the passivation layer 70. The pixel electrode conductive film 81 may be made of a transparent conductor, such as ITO or IZO, or a reflective conductor such as aluminum.

Referring to FIG. 9 and FIG. 1B, the pixel electrode conductive film 81 is patterned to form the pixel electrode 82.

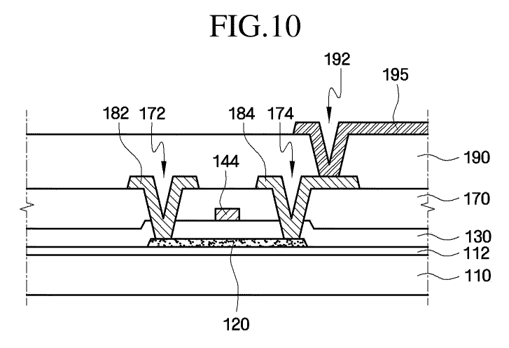

In the above embodiments, a bottom gate structure in which a gate electrode is disposed under an oxide semiconductor layer has been described. However, the present invention is not limited to such a bottom gate structure. That is, a top gate structure in which a gate electrode is disposed on an oxide semiconductor layer can also be applied. A thin-film transistor array panel having the top gate structure will now be described with reference to FIG. 10.

Hereinafter, a thin-film transistor array panel according to a second exemplary embodiment of the present invention will be described in detail. FIG. 10 is a cross-sectional view of the thin-film transistor array panel according to the second exemplary embodiment of the present invention.

Referring to FIG. 10, a buffer layer 112, which may be made of SiOx, SiNx, or SiON, is disposed on an insulating substrate 110.

An oxide semiconductor layer 120 containing a metal inorganic salt and zinc acetate (Zn (O₂CCH₃)₂) is formed on the buffer layer 112. Materials that constitute the oxide semiconductor layer 120 and a method of fabricating the oxide semiconductor layer 120 are substantially identical to those for the oxide semiconductor layer 41 according to the first exemplary embodiment described above.

A gate insulating film 130 is formed on the insulating substrate 110 and the oxide semiconductor layer 120. Like the buffer layer 112, the gate-insulating film 130 may be made of SiOx, SiNx, or SiON.

A gate electrode 144 is formed on the gate insulating film 130 to overlap the oxide semiconductor layer 120.

A first interlayer insulating film 170 is formed on the gate insulating film 130 and the gate electrode 144. The first interlayer insulating film 170 may be a SiOx film, a SiNx film, or a SiON film formed by chemical vapor deposition (CVD). A pair of contact holes 172 and 174 are formed in the first interlayer insulating film 170 and the gate insulating film 130. The contact holes 172 and 174 expose portions of the oxide semiconductor layer 120 that are disposed on both sides of the gate electrode 144.

A source electrode 182 and a drain electrode 184 are formed on the first interlayer insulating film 170 and are electrically connected to the oxide semiconductor layer 120 by the contact holes 172 and 174, respectively.

A second interlayer insulating film 190 is formed on the source electrode 182, the drain electrode 184, and the first interlayer insulating film 170. The second interlayer insulating film 190 is made of an organic material having photosensitivity and superior planarization characteristics. For example, the second interlayer insulating film 190 may be formed of an organic material, such as acrylic resin, using the spin coating method. A contact hole 192, which exposes the drain electrode 184, is formed in the second interlayer insulating film 190.

A pixel electrode 195, which is made of a transparent material, is disposed on the second interlayer insulating film 190. The pixel electrode 195 is electrically connected to the drain electrode 184 by the contact hole 192.

While the present invention has been particularly shown and described with reference to exemplary embodiments thereof, it will be understood by those skilled in the art that various modifications and variations in form and detail may be made therein without departing from the spirit or scope of the invention. The exemplary embodiments should be considered in a descriptive sense only and not for purposes of limitation. Thus, it is intended that the present invention cover the modifications and variations of this invention provided they come within the scope of the appended claims and their equivalents.

What is claimed is:

1. A thin-film transistor array panel, comprising:
a substrate;
an oxide semiconductor layer disposed on the substrate and comprising a metal inorganic salt and zinc acetate;
a gate electrode overlapping with the oxide semiconductor layer;
a gate insulating film disposed between the oxide semiconductor layer and the gate electrode; and
a source electrode and a drain electrode disposed to at least partially overlap the oxide semiconductor layer and separated from each other.

2. The panel of claim 1, wherein the metal inorganic salt comprises at least one metal selected from lithium (Li), sodium (Na), potassium (K), rubidium (Rb), cesium (Cs), beryllium (Be), magnesium (Mg), calcium (Ca), strontium (Sr), barium (Ba), titanium (Ti), zirconium (Zr), hafnium (Hf), vanadium (V), niobium (Nb), tantalum (Ta), chromium (Cr), molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), aluminum (Al), gallium (Ga), indium (In), thallium (Tl), silicon (Si), germanium (Ge), tin (Sn), lead (Pb), phosphorus (P), arsenic (As), antimony (Sb), and bismuth (Bi).

3. The panel of claim 1, wherein the metal organic salt comprises at least one inorganic salt selected from fluorine (F), chlorine (Cl), bromine (Br), iodine (I), NO₃, SO₄, PO₄, C₂O₄, ClO₄, and BF₄.

4. The panel of claim 1, wherein the oxide semiconductor layer is a coated layer comprising a metal compound solution comprising the metal inorganic salt and the zinc acetate.

5. The panel of claim 4, wherein the metal compound solution further comprises a stabilizer.

6. The panel of claim 5, wherein the stabilizer comprises at least one of diketone, amino alcohol, and polyamine.

7. The panel of claim 6, wherein the diketone comprises acetylacetone.

8. The panel of claim 4, wherein a solvent of the metal compound solution comprises alcohol.

9. A method of fabricating a thin-film transistor array panel, the method comprising:
forming an oxide semiconductor layer comprising a metal inorganic salt and zinc acetate on a substrate;
forming a gate electrode overlapping with the oxide semiconductor layer;
forming a gate insulating film, the gate insulating film being disposed between the oxide semiconductor layer and the gate electrode; and
forming a source electrode and a drain electrode to at least partially overlap the oxide semiconductor layer and to be separated from each other.

10. The method of claim 9, wherein the metal inorganic salt comprises at least one metal selected from lithium (Li), sodium (Na), potassium (K), rubidium (Rb), cesium (Cs), beryllium (Be), magnesium (Mg), calcium (Ca), strontium (Sr), barium (Ba), titanium (Ti), zirconium (Zr), hafnium (Hf), vanadium (V), niobium (Nb), tantalum (Ta), chromium (Cr), s molybdenum (Mo), tungsten (W), manganese (Mn), technetium (Tc), rhenium (Re), iron (Fe), ruthenium (Ru), osmium (Os), cobalt (Co), rhodium (Rh), iridium (Ir), nickel (Ni), palladium (Pd), platinum (Pt), copper (Cu), silver (Ag), gold (Au), cadmium (Cd), mercury (Hg), boron (B), aluminum (Al), gallium (Ga), indium (In), thallium (Tl), silicon (Si), germanium (Ge), tin (Sn), lead (Pb), phosphorus (P), arsenic (As), antimony (Sb), and bismuth (Bi).

11. The method of claim 9, wherein the metal organic salt comprises at least one inorganic salt selected from fluorine (F), chlorine (Cl), bromine (Br), iodine (I), NO₃, SO₄, PO₄, C₂O₄, ClO₄, and BF₄.

12. The method of claim 9, wherein forming the oxide semiconductor layer comprises coating a metal compound solution comprising the metal inorganic salt and the zinc acetate on the substrate.

13. The method of claim 12, wherein coating the metal compound solution comprises spin coating, dip coating, bar coating, screen printing, slide coating, roll coating, spray coating, slot coating, dip-pen, inkjet, and nano-dispensing methods.

14. The method of claim 12, wherein forming the oxide semiconductor layer further comprises heat-treating the metal compound solution after coating the metal compound solution on the substrate.

15. The method of claim 14, wherein the heat-treating of the metal compound solution is performed at a temperature in a range from about 100 to about 500° C.

16. The method of claim 12, wherein the metal compound solution further comprises a stabilizer.

17. The method of claim 16, wherein the stabilizer comprises at least one of diketone, amino alcohol, and polyamine.

18. The method of claim 17, wherein the diketone comprises acetylacetone.

19. The method of claim 17, wherein the amino alcohol comprises at least one of ethanolamine, diethanolamine, and triethanolamine.

20. The method of claim 17, wherein the polyamine comprises at least one of ethylenediamine and 1,4-diaminobutane.

21. The method of claim 12, wherein a solvent of the metal compound solution comprises alcohol.
